(19) United States
(12) Patent Application Publication
(10) Pub. No.: US 2024/0258761 A1
(43) Pub. Date: Aug. 1, 2024

(54) Laser with intracavity modulator

(71) Applicant: MARVELL ASIA PTE LTD, Singapore (SG)

(72) Inventors: Xiaoguang He, Diamond Bar, CA (US); Radhakrishnan Nagarajan, Santa Clara, CA (US)

(21) Appl. No.: 18/389,872

(22) Filed: Dec. 20, 2023

Related U.S. Application Data
(60) Provisional application No. 63/441,424, filed on Jan. 26, 2023.

(51) Int. Cl. H01S 3/107; H01S 3/082; H01S 3/083

(52) U.S. Cl. CPC H01S 3/107; H01S 3/082; H01S 3/083

(57) ABSTRACT

An optoelectronic device includes a gain medium configured to amplify laser radiation within a given gain band. A resonant optical cavity contains the gain medium and includes first and second reflectors disposed on first and second sides of the gain medium. A comb filter between the first and second reflectors and configured to pass a set of distinct wavelength sub-bands within the gain band, the set of distinct wavelength sub-bands defining a comb. A plurality of optical ring resonators between the first and second reflectors in series with the comb filter have tunable resonant wavelengths in proximity to different, respective wavelength sub-bands of the comb. A control circuit applies respective control voltages to the optical ring resonators so as to tune the respective resonant wavelengths relative to the respective wavelength sub-bands, thereby modulating the sub-bands in the laser radiation that is output from the device.

### CROSS-REFERENCE TO RELATED APPLICATION

This application claims the benefit of U.S. Provisional Patent Application 63/441,424, filed Jan. 26, 2023, which is incorporated herein by reference.

### FIELD

The present invention relates generally to optoelectronic devices, and particularly to semiconductor lasers.

### BACKGROUND

Wavelength domain multiplexing (WDM) is commonly used in high-speed optical communications to enable multiple communication signals with different carrier wavelengths to be transmitted over the same optical fiber. Some WDM devices use a single laser, emitting radiation at a comb of wavelengths, to provide carrier waves at multiple wavelengths simultaneously. The term “comb,” as used in the present description and in the claims, refers to a set of distinct spectral sub-bands, having respective center wavelengths that are spaced apart by equal steps in wavelength. The term “comb filter” refers to an optical filter having a passband consisting of such a comb, such that the comb filter passes light having a wavelength in any of the distinct spectral sub-bands in the set while blocking wavelengths between the sub-bands in the set. The terms “light” and “optical radiation” are used synonymously in the present description and in the claims to refer to electromagnetic radiation in any of the infrared, visible, and ultraviolet spectral ranges.

Although most lasers operate at a single wavelength, lasers with comb outputs are known in the art. For example, Zhang et al. describe a multi-wavelength laser in an article entitled “Quantum dot SOA/silicon external cavity multi-wavelength laser,” published in Optics Express 23:4 (2015), pages 4666-4671. The device described in the article consists of a quantum dot reflective semiconductor optical amplifier and a silicon-on-insulator chip with a Sagnac loop mirror and microring wavelength filter. The authors showed four major lasing peaks from a single cavity.

As another example, Chen et al. describe a comb laser with a ring modulator in “A comb laser-driven DWDM silicon photonic transmitter based on microring modulators,” published in Optics Express 23:16 (2015), pages 21541-21548. The DWDM transmitter is based on a single quantum dot comb laser and an array of microring resonator-based modulators. The resonant wavelengths of the microrings are thermally tuned to align with the wavelengths provided by the comb laser.

### SUMMARY

Some embodiments of the present invention that are described hereinbelow provide semiconductor laser devices that output optical radiation in a comb of wavelengths, as well as methods for producing and operating such devices.

There is therefore provided, in accordance with an embodiment of the invention, an optoelectronic device, including a gain medium configured to amplify laser radiation within a given gain band. A resonant optical cavity containing the gain medium includes a first reflector disposed on a first side of the gain medium and a second reflector disposed on a second side of the gain medium, opposite the first side. A comb filter, disposed between the first and second reflectors, is configured to pass a set of distinct wavelength sub-bands within the gain band, the set of distinct wavelength sub-bands defining a comb. A plurality of optical ring resonators, disposed between the first and second reflectors in series with the comb filter, have tunable resonant wavelengths in proximity to different, respective wavelength sub-bands of the comb.

A control circuit is coupled to apply respective control voltages to the optical ring resonators so as to tune the respective resonant wavelengths relative to the respective wavelength sub-bands, thereby modulating the sub-bands in the laser radiation that is output from the device.

In some embodiments, the device includes an optical substrate, wherein the comb filter and the plurality of optical ring resonators are disposed on the optical substrate and are interconnected with the gain medium by waveguides on the optical substrate. In a disclosed embodiment, the gain medium and the first reflector define a reflective semiconductor optical amplifier (RSOA) on an active optical chip, and the waveguides and the second reflector define a laser cavity, which is coupled to the RSOA externally to the active optical chip and contains the comb filter and the optical ring resonators. In one embodiment, the laser cavity coupled externally to the active optical chip includes a silicon photonic integrated circuit (PIC) on which the comb filter and the optical ring resonators are disposed.

In a disclosed embodiment, the device includes a bandpass filter that is disposed between the first and second reflectors in series with the comb filter, the bandpass filter having a passband encompassing a subset of the wavelength sub-bands in the comb. Additionally or alternatively, the device includes a phase tuner disposed between the first and second reflectors in series with the comb filter to tune a phase of the resonant optical cavity.

In some embodiments, each of the optical ring resonators includes a respective resonant ring, wherein the control circuitry is configured to adjust the control voltages to modify an effective index of refraction of the resonant ring and thereby tune the respective resonant wavelengths. In a disclosed embodiment, each of the optical ring resonators includes a semiconductor junction in proximity to the respective resonant ring, and the control voltages modify the effective index of refraction by biasing the semiconductor junction.

In one embodiment, the control circuit is configured to switch the sub-bands on and off by tuning the respective resonant wavelengths relative to the respective wavelength sub-bands. Additionally or alternatively, the control circuit is configured to adjust respective intensities of the sub-bands by tuning the respective resonant wavelengths relative to the respective wavelength sub-bands.

There is also provided, in accordance with an embodiment of the invention, a method for generating radiation. The method includes inserting a gain medium configured to amplify laser radiation within a given gain band in a resonant optical cavity. The resonant optical cavity includes a first reflector disposed on a first side of the gain medium and a second reflector disposed on a second side of the gain medium, opposite the first side. A comb filter is inserted in the resonant optical cavity between the first and second reflectors. The comb filter is configured to pass a set of distinct wavelength sub-bands within the gain band, the set of distinct wavelength sub-bands defining a comb. A plurality of optical ring resonators are inserted in the resonant optical cavity between the first and second reflectors in series with the comb filter. The optical ring resonators have tunable resonant wavelengths in proximity to different, respective wavelength sub-bands of the comb. Respective control voltages are applied to the optical ring resonators so as to tune the respective resonant wavelengths relative to the respective wavelength sub-bands, thereby modulating the sub-bands in the laser radiation that is output from the device.

The present invention will be more fully understood from the following detailed description of the embodiments thereof, taken together with the drawings in which:

### BRIEF DESCRIPTION OF THE DRAWINGS

FIG. 1 is a block diagram that schematically illustrates a multi-wavelength laser device, in accordance with an embodiment of the invention;

FIG. 2 is a schematic detail view of a tunable ring resonator, in accordance with an embodiment of the invention;

FIG. 3 is a spectral plot that schematically shows passband and stopband spectra of the ring resonator of FIG. 2, in accordance with an embodiment of the invention;

FIG. 4 is a spectral plot that schematically illustrates tuning of a stopband of the ring resonator of FIG. 2, in accordance with an embodiment of the invention; and

FIG. 5 is a spectral plot that schematically illustrates the output of the device of FIG. 1, in accordance with an embodiment of the invention.

### DETAILED DESCRIPTION

Multi-wavelength semiconductor lasers that are used in WDM applications typically emit a comb of wavelength sub-bands over a wide spectral range. Additional switches or modulators external to the laser cavity are used to select and control the intensities of the wavelength sub-bands to be transmitted over the WDM channels. This approach is energy-inefficient, since much of the optical power output by the laser is discarded.

Embodiments of the present invention that are described herein use a comb filter and optical ring resonators disposed within the optical cavity of a laser device to generate and modulate the wavelength sub-bands. In these embodiments, a gain medium, which amplifies laser radiation within a given gain band, is contained in a resonant optical cavity comprising first and second reflectors on opposing first and second sides of the gain medium. The cavity also contains a comb filter and multiple optical ring resonators arranged in series. The comb filter passes a set of distinct wavelength sub-bands within the gain band. The optical ring resonators have tunable resonant wavelengths in proximity to different, respective wavelength sub-bands of the comb.

To control the spectral output of the laser device, a control circuit applies respective control voltages to the optical ring resonators so as to tune the respective resonant wavelengths relative to the respective wavelength sub-bands. The optical ring resonators serve as filters, with respective stopbands and passbands in wavelength ranges determined by the respective resonant wavelengths. The control circuit is thus able to modulate the wavelength sub-bands of the comb in the laser radiation that is output from the device by controlling the overlap between each sub-band and the resonance of the corresponding ring resonator. In this manner, the individual sub-bands may be turned on and off rapidly by switching the voltages applied to the ring resonators. Alternatively or additionally, the intensities of the sub-bands may be controlled, for example to equalize the intensities, by tuning the resonant wavelengths of the ring resonators relative to the corresponding sub-bands in the comb.

Incorporating the tunable optical ring resonators, along with the comb filter, in the laser cavity, rather than as external elements, is particularly advantageous in terms of power efficiency, since all the optical power output by the laser is concentrated in the desired wavelength sub-bands of the comb. Furthermore, only a small investment of power is needed to tune the ring resonators and thus modulate the laser output. By contrast, when the sub-bands of the comb are switched on and off or otherwise modulated externally to the laser cavity, the power emitted in sub-bands that are unused or attenuated is wasted. The present embodiments thus provide a simple, efficient solution for generating a modulated, multi-wavelength laser output.

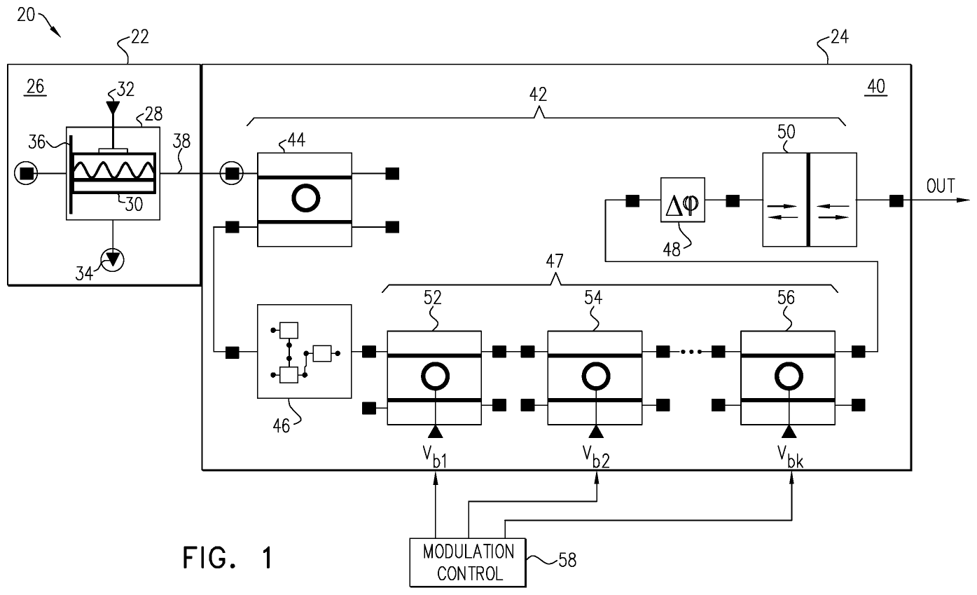

FIG. 1 is a block diagram that schematically illustrates a multi-wavelength laser device 20, in accordance with an embodiment of the invention. Device 20 comprises an active optical chip 22 on a III-V semiconductor substrate 26, such as GaAs or InP, and a photonic integrated circuit (PIC 24) on an optical substrate 40, for example a silicon-on-insulator (SOI) substrate. For mechanical stability and compact packaging, chip 22 may be bonded to optical substrate 40, for example using a suitable adhesive. Alternatively, chip 22 and PIC 24 may be mounted separately and connected, for example, by a suitable optical fiber.

Chip 22 comprises a reflective semiconductor optical amplifier (RSOA 28), comprising an optical gain medium 30, which amplifies laser radiation within a certain gain band, and a reflector 36 formed at the inner end of gain medium 30. Application of a drive voltage between electrodes 32 and 34 on chip 22 gives rise to optical gain in medium 30 across a certain gain band, for example over a band of several tens of nanometers centered at around 1310 nm or 1550 nm depending on the type of gain medium that is used. Gain medium 30 may comprise, for example, GaInAsP, AlGaInAs quantum wells, or InAs quantum dots, which emit light in these gain bands. Reflector 36 may comprise a distributed Bragg reflector (DBR), for example, or a reflective coating on the rear facet of the RSOA. A waveguide 38 on substrate 26 conveys laser radiation into and out of the RSOA at the end opposite reflector 36.

PIC 24 comprises an external laser cavity 42, which is optically coupled to waveguide 38 and terminates in a reflector 50. (Cavity 42 is “external” in the sense that it is not located on chip 22, which contains optical gain medium 30.) Reflector 50 is partially reflecting to allow the multi-wavelength laser beam that is generated by device 20 to exit from the cavity. Cavity 42 contains a comb filter 44 and a bandpass filter 46 in series, along with a phase tuner 48 for adjusting the cavity phase. Comb filter 44 in this embodiment comprises an optical ring resonator, with a ring length chosen so that filter 44 passes a comb of wavelength sub-bands within the gain band of RSOA 28. Thus, multi-wavelength laser device 20 can serve as a beam source for WDM communication applications, for example, with the wavelength spacing between the sub-bands in the comb set equal to the spacing between the WDM channels.

Bandpass filter 46 has a passband encompassing a subset of the wavelength sub-bands in the comb that is defined by comb filter 44. For example, the subset of sub-bands encompassed by the bandpass filter may correspond to the set of wavelengths of the WDM channels, while the remainder of the comb falls outside the passband. In other words, the passband of the bandpass filter encompasses the subset of wavelength sub-bands in the sense that the bandpass filter attenuates the wavelengths within this subset only minimally, while applying stronger attenuation to wavelengths outside the subset. Typically, the passband of bandpass filter 46 is narrower than the gain band of gain medium 30. Because bandpass filter 46 is contained in the laser cavity, only a weak attenuation (on the order of 1-10 dB) is needed to suppress laser activity at wavelengths outside the passband. Bandpass filter 46 may comprise any sort of filter that is suitable for implementation on PIC 24, such as an absorption filter, a diffractive filter, or one or more optical ring resonators.

External laser cavity 42 on PIC 24 also contains a multi-band optical modulator 47, comprising multiple optical ring resonators 52, 54, . . . , 56 in series with comb filter 44. Ring resonators 52, 54, . . . , 56 are configured as band-stop filters, having tunable stopbands at respective resonant wavelengths in proximity to different, respective wavelength sub-bands of the comb that is generated by comb filter 44. In the present example, multi-band optical modulator 47 is assumed to comprise k optical ring resonators, for example k=8. A control circuit 58 applies respective control voltages Vb1, Vb2, . . . , Vbk to optical ring resonators 52, 54, . . . , 56 so as to tune the respective resonant wavelengths relative to the respective wavelength sub-bands, thereby modulating the sub-bands in the laser radiation that is output from the device. Details of the optical ring resonators and their mode of operation are described with reference to the figures that follow.

The terms “bandpass filter” and “band-stop filter” are used in the present description and in the claims in the conventional sense of the terms. A bandpass filter is a device that passes wavelengths within a certain range, referred to as the “passband” of the filter, and attenuates wavelengths outside the passband. A band-stop filter attenuates wavelengths within a certain range, referred to as the “stopband” of the filter, while passing wavelengths outside the stopband. The difference in attenuation applied by the filter within and outside the passband or stopband can be large or small, depending on application requirements. An advantage of intracavity filters, such as the filters on PIC 24 in FIG. 1, is that only a small difference in attenuation at a given wavelength can give rise to a large change in the laser output power at the given wavelength.

Modulation control circuit 58 typically comprises electronic hardware logic, which may be hard-wired or programmable, with suitable interfaces for applying control voltages to the optical ring resonators. In the implementation that is described below, these control voltages are bias voltages, which are applied to modify the effective indexes of refraction of the resonant rings in the optical ring resonators and thus tune their respective resonant wavelengths. Control circuit 58 may also comprise input interfaces (not shown), which receive optical and/or electronic feedback signals from PIC 24 and/or from other sources and modify the control voltages accordingly. Alternatively or additionally, control circuit 58 may comprise a programmable processor, which performs at least some of the functions that are described herein under the control of program instructions in software or firmware.

FIG. 2 is a schematic detail view of tunable ring resonator 52, in accordance with an embodiment of the invention. The other ring resonators 54, . . . , 56 on PIC 24 are typically of similar design.

Optical ring resonator 52 comprises a resonant ring 64 and four ports: a port 60 serving as an input, ports 62 and 66 as outputs, and an additional port 67, which is not used in the present embodiment. Port 66 is referred to as a “drop port,” while port 62 is referred to as a “pass port.” When port 62 is used as the output port, as in ring resonators 52, 54, . . . , 56, destructive interference on ring 64 causes the optical ring resonator to function as a notch-type band-stop filter with a stopband in proximity to one of the wavelength sub-bands of comb filter 44.

The operation of each optical ring resonator 52, 54, . . . , 56 depends on the length of resonant ring 64, which determines the spacing between the resonant wavelengths of the ring and hence the sub-bands that are passed or blocked. The center wavelength λC of the stopband is given by the resonance formula λ_{c}=nL/m, wherein n is the effective refractive index of resonant ring 64, L is the length (circumference) of the resonant ring, and m is an integer. On this basis, the lengths of resonant rings 64 in optical ring resonators 52, 54, . . . , 56 are chosen so that the respective center wavelengths of the stopbands of the optical ring resonators are in proximity to different, respective wavelength sub-bands of the comb that is generated by comb filter 44.

To tune the stopband of optical ring resonator 52, control circuit 58 (FIG. 1) applies a control voltage 70, which modifies the effective index of refraction n of resonant ring 64. In the present example, optical ring resonator 52 comprises a semiconductor junction 68 in proximity to resonant ring 64. Control voltage 70 modifies the effective index of refraction n by biasing semiconductor junction 68. For high-speed modulation, control voltage 70 is typically set to apply a reverse bias across junction 68.

Alternatively, depending on application requirements, other mechanisms may be applied to tune the effective length of resonator ring 64, for example thermal tuning or piezoelectric tuning.

Further alternatively, ring resonators 52 may be configured as notch filters, with the output of each ring resonator taken from drop port 66, rather than pass port 62. In this case, however, ring resonators 52 are coupled together in parallel, rather than in series as in the embodiment shown in FIG. 1, and the outputs from the pass ports are multiplexed together into a single waveguide.

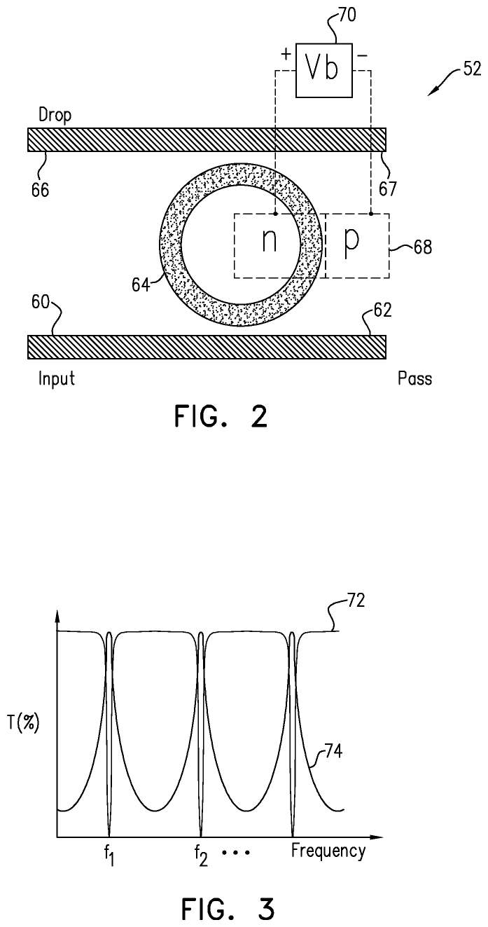

FIG. 3 is a spectral plot that schematically shows a stopband spectrum 72 and a passband spectrum 74 of optical ring resonator 52, in accordance with an embodiment of the invention. Spectrum 72 represents the transmittance (T) of a guided beam from input port 60 to output port 62 (the pass port) as a function of frequency, while spectrum 74 represents the transmittance from input port 60 to drop port 66. Spectrum 72 comprises multiple stopbands at respective resonant frequencies f1, f2, . . . , which are spaced apart by a frequency spacing Δf=c/nL, wherein c is the speed of light. The center frequency of one of the stopbands is in proximity to a corresponding frequency sub-band of the comb generated by comb filter 44 (FIG. 1).

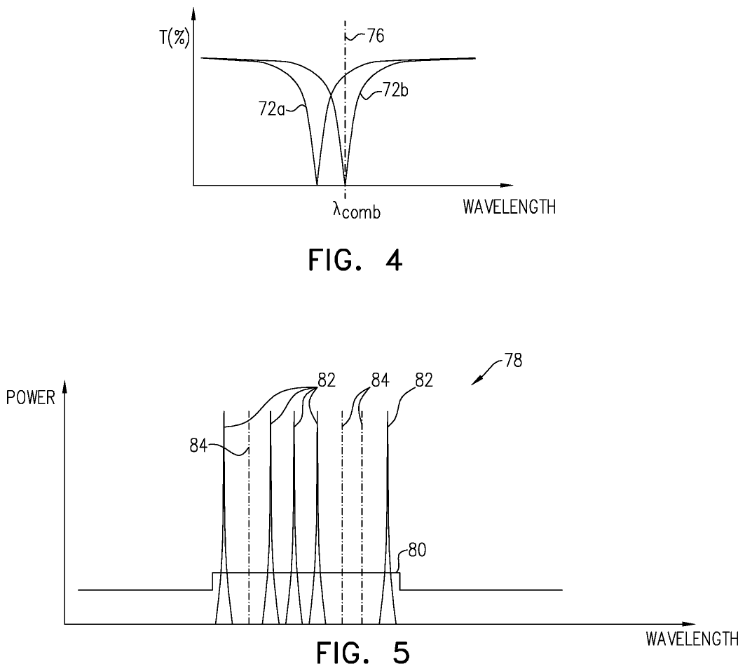

FIG. 4 is a spectral plot that schematically illustrates tuning of stopband 72 of optical ring resonator 52, in accordance with an embodiment of the invention. The central wavelength of stopband 72 is near a center wavelength 76, λcomb, of one of the wavelength sub-bands in the comb generated by comb filter 44. In the pictured example, switching on control voltage 70 gives rise to a shifted stopband 72a, which causes only minimal attenuation at wavelength 76. Switching off control voltage 70 results in a default stopband 72b, which coincides with center wavelength 76, so that the corresponding wavelength sub-band will be strongly attenuated and thus switched off in the laser output.

In practice, the shift of stopband 72 relative to center wavelength 76 may be tuned by adjusting the value of control voltage 70. This tuning may be used both to align the stopband with the wavelength sub-band and to adjust the attenuation that is applied to the wavelength sub-band at the edge of the stopband (for example, the minor attenuation that is applied by shifted stopband 72a). This adjustment of the stopband can be useful in adjusting the respective intensities of the sub-bands in the output from device 20 by tuning the respective resonant wavelengths of the ring oscillators relative to the respective wavelength sub-bands. For example, control circuit 58 may set the control voltages applied to optical ring resonators 52, 54, . . . , 56 based on feedback so that all the sub-bands in the comb have equal intensities.

FIG. 5 is a plot that schematically shows an output spectrum 78 of laser device 20, in accordance with an embodiment of the invention. Spectrum 78 comprises a comb of equally-spaced wavelength sub-bands 82, 84, which are encompassed by a passband 80 of bandpass filter 46. By appropriate control of the voltages applied to the respective optical ring resonators 52, 54, . . . , 56, control circuit 58 has switched sub-bands 82 on, while switching sub-bands 84 off. The sub-bands in spectrum 78 may be switched on and off at the rate of modulation of control voltages 70, with only a minimal investment of switching power.

Thus, the embodiments described above are cited by way of example, and the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. An optoelectronic device, comprising:
a gain medium configured to amplify laser radiation within a given gain band;
a resonant optical cavity containing the gain medium and comprising:
a first reflector disposed on a first side of the gain medium;
a second reflector disposed on a second side of the gain medium, opposite the first side;
a comb filter, disposed between the first and second reflectors and configured to pass a set of distinct wavelength sub-bands within the gain band, the set of distinct wavelength sub-bands defining a comb; and
a plurality of optical ring resonators, disposed between the first and second reflectors in series with the comb filter and having tunable resonant wavelengths in proximity to different, respective wavelength sub-bands of the comb; and
a control circuit coupled to apply respective control voltages to the optical ring resonators so as to tune the respective resonant wavelengths relative to the respective wavelength sub-bands, thereby modulating the sub-bands in the laser radiation that is output from the device.

2. The device according to claim 1, comprising an optical substrate, wherein the comb filter and the plurality of optical ring resonators are disposed on the optical substrate and are interconnected with the gain medium by waveguides on the optical substrate.

3. The device according to claim 2, wherein the gain medium and the first reflector define a reflective semiconductor optical amplifier (RSOA) on an active optical chip, and wherein the waveguides and the second reflector define a laser cavity, which is coupled to the RSOA externally to the active optical chip and contains the comb filter and the optical ring resonators.

4. The device according to claim 3, wherein the gain medium comprises a III-V semiconductor material, and wherein the laser cavity coupled externally to the active optical chip comprises a silicon photonic integrated circuit (PIC) on which the comb filter and the optical ring resonators are disposed.

5. The device according to claim 1, comprising a bandpass filter that is disposed between the first and second reflectors in series with the comb filter, the bandpass filter having a passband encompassing a subset of the wavelength sub-bands in the comb.

6. The device according to claim 1, comprising a phase tuner disposed between the first and second reflectors in series with the comb filter to tune a phase of the resonant optical cavity.

7. The device according to claim 1, wherein each of the optical ring resonators comprises a respective resonant ring, wherein the control circuitry is configured to adjust the control voltages to modify an effective index of refraction of the resonant ring and thereby tune the respective resonant wavelengths.

8. The device according to claim 7, wherein each of the optical ring resonators comprises a semiconductor junction in proximity to the respective resonant ring, and wherein the control voltages modify the effective index of refraction by biasing the semiconductor junction.

9. The device according to claim 1, wherein the control circuit is configured to switch the sub-bands on and off by tuning the respective resonant wavelengths relative to the respective wavelength sub-bands.

10. The device according to claim 1, wherein the control circuit is configured to adjust respective intensities of the sub-bands by tuning the respective resonant wavelengths relative to the respective wavelength sub-bands.

11. A method for generating radiation, the method comprising:
inserting a gain medium configured to amplify laser radiation within a given gain band in a resonant optical cavity, the resonant optical cavity comprising a first reflector disposed on a first side of the gain medium and a second reflector disposed on a second side of the gain medium, opposite the first side;
inserting in the resonant optical cavity a comb filter between the first and second reflectors, the comb filter being configured to pass a set of distinct wavelength sub-bands within the gain band, the set of distinct wavelength sub-bands defining a comb;
inserting in the resonant optical cavity a plurality of optical ring resonators between the first and second reflectors in series with the comb filter, the optical ring resonators having tunable resonant wavelengths in proximity to different, respective wavelength sub-bands of the comb; and
applying respective control voltages to the optical ring resonators so as to tune the respective resonant wavelengths relative to the respective wavelength sub-bands, thereby modulating the sub-bands in the laser radiation that is output from the device.

12. The method according to claim 11, wherein inserting the comb filter and the plurality of optical ring resonators comprises forming the comb filter and the optical ring resonators on an optical substrate and coupling the gain medium to the comb filter and the optical ring resonators through waveguides on the optical substrate.

13. The method according to claim 12, wherein inserting the gain medium comprises providing a reflective semiconductor optical amplifier (RSOA) comprising the gain medium and the first reflector on an active optical chip, and wherein coupling the gain medium to the comb filter and the optical ring resonators comprises coupling to the RSOA a laser cavity, which is external to the active optical chip and is defined by the waveguides and the second reflector and contains the comb filter and the optical ring resonators.

14. The device according to claim 13, wherein the gain medium comprises a III-V semiconductor material, and wherein coupling the laser cavity comprises providing a silicon photonic integrated circuit (PIC) on which the comb filter and the optical ring resonators are disposed.

15. The method according to claim 11, comprising inserting a bandpass filter between the first and second reflectors in series with the comb filter, the bandpass filter having a passband encompassing a subset of the wavelength sub-bands in the comb.

16. The method according to claim 11, comprising inserting a phase tuner between the first and second reflectors in series with the comb filter to tune a phase of the laser radiation in the resonant optical cavity.

17. The method according to claim 1, wherein each of the optical ring resonators comprises a respective resonant ring, wherein applying the respective control voltages comprises adjusting the control voltages to modify an effective index of refraction of the resonant ring and thereby tune the respective resonant wavelengths.

18. The method according to claim 17, wherein each of the optical ring resonators comprises a semiconductor junction in proximity to the respective resonant ring, and wherein adjusting the control voltages comprises biasing the semiconductor junction.

19. The method according to claim 11, wherein applying the respective control voltages comprises switching the sub-bands on and off by tuning the respective resonant wavelengths relative to the respective wavelength sub-bands.

20. The method according to claim 11, wherein applying the respective control voltages comprises adjusting respective intensities of the sub-bands by tuning the respective resonant wavelengths relative to the respective wavelength sub-bands.
